(19) United States
(12) Patent Application Publication
(10) Pub. No.: US 2006/0138540 A1
(43) Pub. Date: Jun. 29, 2006

(54) Semiconductor wafer having a semiconductor layer and an electrically insulating layer beneath it, and process for producing it

(75) Inventors: Dirk Dantz, Koenigslutter am Elm (DE); Andreas Huber, Garching (DE); Brian Murphy, Pfarrkirchen (DE); Reinhold Wahlich, Tittmoning (DE)

Correspondence Address: BROOKS KUSHMAN P.C., 1000 TOWN CENTER, TWENTY-SECOND FLOOR, SOUTHFIELD, MI, 48075, US

(73) Assignee: Siltronic AG, Munich (DE)

(21) Appl. No.: 11/314,568

(22) Filed: Dec. 21, 2005

(30) Foreign Application Priority Data
Dec. 23, 2004 (DE) 10 2004 062 356.2

(51) Int. Cl. H01L 27/12

(52) U.S. Cl. 257/347

(57) ABSTRACT

The invention relates to a semiconductor wafer, which, at its surface comprises a semiconductor surface layer with a thickness in the range from 3 nm to 200 nm having no hole defects, and which comprises an adjoining electrically insulating layer beneath the semiconductor surface layer.

### BACKGROUND OF THE INVENTION

1. Field of the Invention

The present invention relates to a semiconductor wafer with a semiconductor layer without hole defects and an electrically insulating layer beneath it, for example an SOI wafer, and to a process for producing it by a heat treatment of the semiconductor wafer.

2. Description of the Related Art

SOI (silicon on insulator) wafers are generally produced by transferring a silicon layer from what is known as a donor wafer to a handle wafer, also known as a base wafer. Processes for producing SOI wafers by transferring a silicon layer are described, for example, in EP 533551 A1, WO 98/52216 A1 and WO 03/003430 A2. SOI wafers comprise a handle wafer and a silicon top layer (device layer) joined thereto. The silicon top layer forms what is known as the “active layer,” intended for the fabrication of electronic components. Either the entire handle wafer consists of an electrically insulating material, such as glass or sapphire, or the silicon top layer is joined to the handle wafer via an electrically insulating interlayer, consisting for example of silicon oxide, In the latter case, the interlayer is known as a buried oxide layer, or “BOX”, and the handle wafer does not have to be an insulator, but rather may, for example, be a semiconductor wafer, preferably a silicon wafer.

Very high demands are imposed on the silicon top layer. By way of example, the top layer should not include any hole defects. Hole defects are holes in the top layer which may form, inter alia, as a result of the layer transferred from the donor wafer containing COPs (crystal originated particles; agglomerations of vacancies) which exceed a critical size. Metal contamination or defects caused by joining the donor wafer to the handle wafer can also lead to HF defects. When the top layer is treated with aqueous hydrofluoric acid solution (HF), this solution may penetrate through the holes to the silicon oxide layer and locally dissolve the latter. The presence of hole defects has an adverse effect on the function of components which are fabricated on the top layer. See, e.g., A. J. Auberton-Hervé, T. Barge, F. Metral, M. Bruel, B. Aspar, H. Moriceau, THE ELECTROCHEM. SOC. PV98-1 (1998) 1341.

Hole defects caused by COPs can be substantially avoided if epitaxially coated or COP-free silicon wafers are used as the donor wafers. Hole defects which are caused by metal contamination can be reduced by a multi-stage heat treatment in defined temperature ranges, and with strictly defined heat-up and cooling rates (EP 1193739 A2, EP 1193749 A2). The third group of hole defects, which are caused by defects resulting from the donor wafer being joined to the handle wafer, can be reduced by minimizing the particle contamination of the handle wafer and donor wafer before joining. However, experience has shown that in practice it has been impossible to produce an SOI wafer which is completely devoid of hole defects.

EP 971395 A1 discloses a process in which the thickness of the silicon layer of an SOI wafer is increased considerably, for example from 0.5 μm to 2 μm, after it has been transferred to the handle wafer, by deposition of an epitaxial layer. However, for most applications in the microelectronics sector, it is necessary for the semiconductor layers to be as thin as possible.

Furthermore, WO 00/63954 A1 discloses a process in which the silicon layer of an SOI wafer is subjected to an etching treatment at a high temperature under an etching atmosphere, for example using a hydrogen halide, additionally containing a silane as well. This process is used to reduce the surface roughness and possibly the thickness of the silicon layer. Similar processes have also been disclosed for reducing the surface roughness of conventional silicon wafers, cf. for example EP 1160360 A1.

Each hole defect which is present on the semiconductor wafer prior to the fabrication of electronic components leads to a component which does not function. Therefore, it is of considerable economic importance to avoid even a very small number of hole defects.

### SUMMARY OF THE INVENTION

Therefore, an object of the invention is the production of an SOI wafer with a thin semiconductor layer which leads to an increased yield during the fabrication of electronic components. This and other objects are achieved by a semiconductor wafer, which at its surface comprises a semiconductor layer with a thickness in the range from 3 nm to 200 nm without any hole defects, and which has an adjoining electrically insulating material layer beneath it.

### DETAILED DESCRIPTION OF THE PREFERRED EMBODIMENT(S)

In the context of the invention, the term “hole defects” is to be understood as meaning all holes in the semiconductor layer which extend from the surface of the semiconductor layer to the boundary surface between the semiconductor layer and the insulator layer. These holes can be detected using suitable etching processes; optical methods, e.g. light-scattering methods, optical microscopy; or scanning microscopy, e.g. scanning electron microscopy=SEM, transmission electron microscopy=TEM, or atomic force microscopy=AFM.

Semiconductor wafers produced in accordance with the invention do not have any hole defects and therefore have no resulting yield losses during the fabrication of electronic components.

The semiconductor material of the layer may, for example, be silicon, germanium or silicon-germanium. In general, the semiconductor material of the layer is monocrystalline. The semiconductor material of the layer may also be strained, for example strained silicon.

The layer beneath the layer of semiconductor material may consist of any desired electrically insulating material. The layer may be a handle wafer of an electrically insulating material, for example glass, quartz or sapphire. However, the layer may also be a thin film which in turn rests on a handle wafer consisting, for example, of a semiconductor material. The thin electrically insulating layer preferably consists of an oxide of the same semiconductor material as the semiconductor layer or handle wafer. The semiconductor material of the handle wafer is generally silicon.

What are known as “SOI wafers”, in which the semiconductor layer consists of single-crystal silicon, the thin electrically insulating layer consists of silicon oxide and the handle wafer consists of polycrystalline or more preferably single-crystal silicon, are particularly important. Semiconductor wafers of similar structure in which the semiconductor layer consists of germanium (GOI wafers) or silicon-germanium (SGOI wafers), are also known.

In the case of SOI wafers and similar wafers in which the semiconductor layer is scarcely attacked by hydrofluoric acid (HF), whereas the layer of electrically insulating material is extensively attacked by hydrofluoric acid (HF), hole defects can be prepared by a treatment for 15 minutes with a 49% strength aqueous hydrofluoric acid solution and then counted. The hydrofluoric acid leads to undercut etching of the semiconductor layer. This takes place at the locations at which the semiconductor layer is greatly disrupted or is not present and at which the hydrofluoric acid can directly reach the electrically insulating layer. Therefore, in the case of the known wafer types, the hole defects are also known as HF defects.

The invention also relates to a process for the heat treatment of a semiconductor wafer comprising a semiconductor layer and an adjoining electrically insulating layer beneath it, at a temperature in the range from 750° C. to 1,300° C. under an inert or reducing atmosphere, the atmosphere, at least from time to time, containing a gaseous compound of the semiconductor material, so that semiconductor material is deposited on the surface of the semiconductor layer, wherein the thickness of the semiconductor layer following the heat treatment does not differ significantly from the thickness of the semiconductor layer before the heat treatment. It is preferable for the process to be used to produce a semiconductor wafer, the semiconductor layer of which is free of hole defects. It is also preferable for the thickness of the semiconductor layer, following the heat treatment, to differ by no more than 20%, more preferably by no more than 10%, from the thickness of the semiconductor layer before the heat treatment.

As a result of the inventive process, the hole defects which are present in the semiconductor layer after production of the semiconductor wafer are subsequently annealed due to the semiconductor wafer being exposed to an atmosphere which, under the selected conditions, allows the deposition of small quantities of the semiconductor material on the semiconductor layer and at the same time stimulates surface diffusion on the semiconductor layer. Therefore, holes in the semiconductor layer are subsequently annealed, irrespective of their origin, and without the thickness of the semiconductor layer increasing significantly.

It has been surprisingly discovered that hole defects in the semiconductor layer can be annealed particularly effectively if a slight deposition of semiconductor material on the surface takes place, or if deposition and removal are in balance. According to the invention, this is expressed by the thickness of the semiconductor layer not changing significantly during the treatment. A process which substantially removes material, as described in WO 00/63954 A1, although suitable for smoothing the surface, is not suitable for closing up the hole defects. On the other hand, the process described in EP 971395 A1 is associated with a considerable increase in the layer thickness of the semiconductor layer and is therefore unsuitable for most applications, since it is generally necessary for the layers to be as thin as possible. Therefore, according to the invention it is necessary for the layer thickness not to change significantly during the process, preferably by no more than 20%.

The core concept of the inventive process is a heat treatment under an inert or reducing atmosphere which contains a gaseous compound of the semiconductor material, with semiconductor material being deposited on the surface of the semiconductor layer during at least part of the heat treatment. The semiconductor material is the material of which the semiconductor layer consists. For example, if the semiconductor layer consists of silicon, the gaseous compound of the semiconductor material used may, for example, be a silane, for example, dichlorosilane (SiH₂Cl₂), or a mixture of silanes.

The deposition of semiconductor material takes place in an environment in which surface diffusion is stimulated on the surface of the semiconductor layer. Since an increase in the thickness of the semiconductor layer is not generally desired, it is preferable for the conditions to be selected in such a way as to produce a very low deposition rate. It is preferable for the parameters of the deposition to be selected in such a way that the deposition rate is in the range of from 5 to 50 nm/min, and the duration of the deposition is adjusted in view of the deposition rate, so that hole defects are closed up, and at the same time the required change in layer thickness is not exceeded.

Under conditions which stimulate surface diffusion, even the deposition of very small quantities of the semiconductor material leads to a relatively high number of mobile atoms on the surface of the semiconductor layer. In an attempt to minimize the total energy of the system, i.e. to produce a smooth, continuous surface, the mobile atoms preferably accumulate at the disturbed or weakened regions of the semiconductor layer which are accessible to them. The result of this is that the disturbed locations or hole defects in the semiconductor layer are annealed or closed up during heat treatment. The mobility of the atoms of the semiconductor material rises as the temperature increases and as the pressure drops in an inert or reducing atmosphere, which preferably consists of hydrogen or noble gases such as argon, or mixtures thereof.

During heat treatment, the pressure is preferably in the range from 10⁻⁵ Pa to 10⁴ Pa. The duration of the overall heat treatment is preferably between one second and one hour. The deposition may take place continuously throughout the entire duration of the heat treatment, at intervals, or just temporarily. The resistance of the deposited layer can be adjusted by adding dopant-containing gases (e.g. diborane or phosphine).

In a preferred embodiment of the invention, the atmosphere used during the heat treatment does not contain any oxidizing constituents. In another preferred embodiment, the atmosphere, at least at times, also contains an etching constituent, so that material is removed from the semiconductor layer. The etching constituent may, for example, be a halogen compound, e.g. hydrogen fluoride (HF), hydrogen chloride (HCl), hydrogen bromide (HBr), hydrogen iodide (HI), sulfur hexafluoride (SF₆), nitrogen trifluoride (NF₃), tetrafluoromethane (CF₄) or hexfluoroethane (C₂F₆). To enable the removal of material to be accurately controlled, the parameters of the material removal reaction (e.g. flow of the etching constituent) are selected in such a way that very low material-removal rates in the range from 1 to 20 nm/min result.

The etching constituent and the gaseous compound of the semiconductor material may be simultaneously present in the atmosphere, so that semiconductor material is simultaneously deposited on the semiconductor layer and removed. On the other hand, however, the atmosphere may also contain the compound of the semiconductor material and the etching constituent alternately, so that semiconductor material is alternately deposited and removed. The order in which the two substeps are carried out is arbitrary, and the substeps may also be repeated one or more times. Following preparation of the hole defect-free wafer, the semiconductor surface layer may be coated by additional semiconductor layers by standard techniques.

### EXAMPLES

### Example 1

A cleaned SOI wafer with a silicon top layer of <001> orientation and a thickness of 120 nm was loaded into a CVD reactor suitable for subatmospheric pressures. At a temperature of 1,050° C., oxygen and carbon remaining on the wafer surface were removed by flushing with hydrogen gas. Silicon was deposited using dichlorosilane (SiH₂Cl₂) at a temperature of 1,050° C. and a pressure of 2.7 kPa with a deposition rate of 10 μm/min of silicon. The deposition was restricted to the first minute. Then, the heat treatment was continued under the same conditions without further deposition. The carrier gas used was a mixture of argon and hydrogen. After the heat treatment had ended, the SOI wafer was tested for HF defects. The SOI wafer did not have any HF defects.

### Example 2

A cleaned SOI wafer with a silicon top layer of <001> orientation and a thickness of 120 nm was loaded into a CVD reactor suitable for subatmospheric pressures. At a temperature of 1,050° C., the oxygen and carbon remaining on the wafer surface were removed by flushing with hydrogen gas. Silicon was deposited using dichlorosilane (SiH₂Cl₂) at a temperature of 1,050° C. and a pressure of 4.0 kPa in two intervals with a deposition rate of 10 nm/min in the first and 20 nm/min in the second interval. The first interval lasted for 30 seconds and the second for 15 seconds. After each of the deposition intervals, the processes were continued without further deposition. The carrier gas used was hydrogen. After heat treatment had ended, the SOI wafer was tested for HF defects. The SOI wafer did not have any HF defects.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A semiconductor wafer comprising a semiconductor surface layer with a thickness in the range of from 3 nm to 200 nm and having no hole defects, and an adjoining electrically insulating layer between said semiconductor surface layer and a semiconductor substrate.

2. The semiconductor wafer of claim 1, wherein the semiconductor layer comprises silicon, and the electrically insulating material comprises silicon oxide.

3. A process for eliminating hole defects in a wafer comprising a semiconductor wafer with a semiconductor surface layer and an adjoining electrically insulating layer beneath it, comprising heat treating the wafer at a temperature in the range from 750° C. to 1,300° C. under an inert or reducing atmosphere, the atmosphere, at some time during the heat treating containing a gaseous compound of the semiconductor material, and depositing semiconductor material on the surface of the semiconductor layer, wherein the thickness of the semiconductor layer following the heat treatment does not differ significantly from the thickness of the semiconductor layer before the heat treatment, and hole defects are decreased in the surface layer.

4. The process of claim 3, wherein the semiconductor surface layer is free of hole defects after said heat treating.

5. The process of claim 3, wherein the thickness of the semiconductor layer following heat treating differs by no more than 20% from the thickness of the semiconductor layer before heat treating.

6. The process of claim 4, wherein the thickness of the semiconductor layer following heat treating differs by no more than 20% from the thickness of the semiconductor layer before heat treating.

7. The process of claim 3, wherein the thickness of the semiconductor layer following heat treating differs by no more than 10% from the thickness of the semiconductor layer before heat treating.

8. The process of claim 4, wherein the thickness of the semiconductor layer following heat treating differs by no more than 10% from the thickness of the semiconductor layer before heat treating.

9. The process of claim 3, atmosphere does not contain any oxidizing constituents.

10. The process of claim 3, atmosphere during at least a portion of heat treating contains an etching constituent which removes material from the semiconductor layer.

11. The process of claim 10, wherein the etching constituent comprises a halogen compound.

12. The process of claim 10, wherein the atmosphere simultaneously contains the compound of the semiconductor material and the etching constituent during at least a portion of heat treating, such that semiconductor material is simultaneously deposited on the semiconductor layer and removed.

13. The process of claim 10, wherein the atmosphere contains the compound of the semiconductor material and the etching constituent alternately during at least a portion of heat treating, such that semiconductor material is alternately deposited and removed.

14. The process of claim 3, wherein the heat treating is conducted in a pressure range from 10⁻⁵ Pa to 10⁴ Pa.

15. A semiconductor wafer comprising a semiconductor handle wafer, an insulating layer, and a semiconductor surface layer adjoining the insulating layer, the semiconductor surface layer free of hole defects, and prepared by the process of claim 3.

16. A semiconductor wafer comprising a semiconductor handle wafer, an insulating layer, and a semiconductor surface layer adjoining the insulating layer, the semiconductor surface layer free of hole defects, and prepared by the process of claim 5.

17. A semiconductor wafer comprising a semiconductor handle wafer, an insulating layer, and a semiconductor surface layer adjoining the insulating layer, the semiconductor surface layer free of hole defects, and prepared by the process of claim 6.

18. A semiconductor wafer comprising a semiconductor handle wafer, an insulating layer, and a semiconductor surface layer adjoining the insulating layer, the semiconductor surface layer free of hole defects, and prepared by the process of claim 10.

19. A semiconductor wafer comprising a semiconductor handle wafer, an insulating layer, and a semiconductor surface layer adjoining the insulating layer, the semiconductor surface layer free of hole defects, and prepared by the process of claim 12.

20. A semiconductor wafer comprising a semiconductor handle wafer, an insulating layer, and a semiconductor surface layer adjoining the insulating layer, the semiconductor surface layer free of hole defects, and prepared by the process of claim 13.
